(19) United States
(12) Patent Application Publication
(10) Pub. No.: US 2025/0357727 A1
(43) Pub. Date: Nov. 20, 2025

(54) LIGHT EMITTING DEVICE AND RANGING DEVICE

(71) Applicant: CANON KABUSHIKI KAISHA, Tokyo (JP)

(72) Inventors: TAKAKO SUGA, Kanagawa (JP); TAKESHI UCHIDA, Kanagawa (JP); TATSURO UCHIDA, Tokyo (JP); YUKI KITAZAWA, Kanagawa (JP)

(21) Appl. No.: 19/193,767

(22) Filed: Apr. 29, 2025

(30) Foreign Application Priority Data
May 15, 2024 (JP) 2024-079726

(51) Int. Cl. H01S 5/183; G01S 7/481; G01S 17/931; H01S 5/026; H01S 5/042

(52) U.S. Cl. CPC H01S 5/18377; G01S 7/4816; G01S 17/931; H01S 5/0261; H01S 5/0428

(57) ABSTRACT

Light emitting device(s), range device(s), and one or more movable bodies are provided herein. Light emitting device(s) may include a first light emitting element and a second light emitting element formed on a common semiconductor substrate, and a driving unit that applies drive voltage to each of the first light emitting element and the second light emitting element. Each of the first light emitting element and the second light emitting element may include a first reflector formed on the semiconductor substrate, a resonator formed on the first reflector and disposed on or adjacent to a saturable absorption layer, and a second reflector formed on the resonator, and where drive voltage is applied to each of the first light emitting element and the second light emitting element at the same timing, the first light emitting element and the second light emitting element respectively emit pulse light at different timings.

### BACKGROUND

### Technical Field

One or more features of the present disclosure relate to one or more embodiments of a light emitting device and a ranging device.

### Description of the Related Art

Japanese Patent Application Laid-Open No. 2022-176886 discloses a VCSEL (Vertical Cavity Surface Emitting LASER) capable of emitting a pulse light having a high peak value. The VCSEL has a saturable absorption layer. The saturable absorption layer absorbs light and accumulates carriers for a certain amount of time from a start of current injection, thereby delaying a start of laser oscillation. Accordingly, the VCSEL can accumulate carriers exceeding a threshold carrier density in an active layer, and the VCSEL can emit a high peak value pulse light.

However, although it is preferable to reduce the carriers accumulated in the saturable absorption layer every time the high peak value pulse light is emitted, it takes time to reduce the carriers. Therefore, it is difficult to emit the high peak value pulse light at short intervals.

### SUMMARY

One or more objects of the present disclosure is/are to provide one or more embodiments of a light emitting device that operate to emit a high peak value pulse light at short intervals and one or more embodiments of a ranging device that operate to emit a high peak value pulse light at short intervals.

According to one or more aspects that may be used in one or more embodiments of the present disclosure, there is provided one or more embodiments of a light emitting device that may include: a first light emitting element and a second light emitting element formed on a common semiconductor substrate; and a driving unit that operates to apply drive voltage to each of the first light emitting element and the second light emitting element, wherein each of the first light emitting element and the second light emitting element may include: a first reflector formed on the semiconductor substrate, a resonator formed on the first reflector and the resonator being disposed on or adjacent to a saturable absorption layer, and a second reflector formed on the resonator, wherein, in a case where the drive voltage is applied to each of the first light emitting element and the second light emitting element at the same timing, the first light emitting element and the second light emitting element respectively emit a pulse light at different timings.

According to other aspects of the present disclosure, one or more additional light emitting devices, one or more ranging devices, one or more movable bodies, one or more light emitting methods, and one or more storage mediums are discussed herein.

Further features of the present disclosure will become apparent from the following description of exemplary embodiments with reference to the attached drawings.

### BRIEF DESCRIPTION OF THE DRAWINGS

FIG. 1 is a plan view of a light emitting device according to one or more embodiments of the present disclosure.

FIG. 2 is a cross-sectional view of a light emitting element that may be used in one or more embodiments of the present disclosure.

FIG. 3 is a diagram illustrating a waveform of a high peak value pulse light according to one or more embodiments of the present disclosure.

FIG. 4A and FIG. 4B are diagrams illustrating a relationship between an emission interval and light intensity of a high peak value pulse light according to a comparative example that may be used for one or more embodiments of the present disclosure.

FIG. 5 is a diagram illustrating a relationship between an emission interval and light intensity ratio in a normal pulse light and a high peak value pulse light according to a comparative example that may be used for one or more embodiments of the present disclosure.

FIG. 6 is a cross-sectional view of a light emitting element that may be used in one or more embodiments of the present disclosure.

FIG. 7 is a cross-sectional view of a light emitting element that may be used in one or more embodiments of the present disclosure.

FIG. 8 is a plan view of a light emitting device that may be used in one or more embodiments of the present disclosure.

FIG. 9 is a cross-sectional view of a light emitting element that may be used in one or more embodiments of the present disclosure.

FIG. 10 is a diagram illustrating a waveform of a high peak value pulse light that may be used in one or more embodiments of the present disclosure.

FIG. 11 is a plan view of a light emitting device that may be used in one or more embodiments of the present disclosure.

FIG. 12 is a plan view of a light emitting device that may be used in one or more embodiments of the present disclosure.

FIG. 13A and FIG. 13B are block diagrams of an imaging system and a movable body that may be used in one or more embodiments of the present disclosure.

### DESCRIPTION OF THE EMBODIMENTS

### Details of One or More Embodiments Follow Below

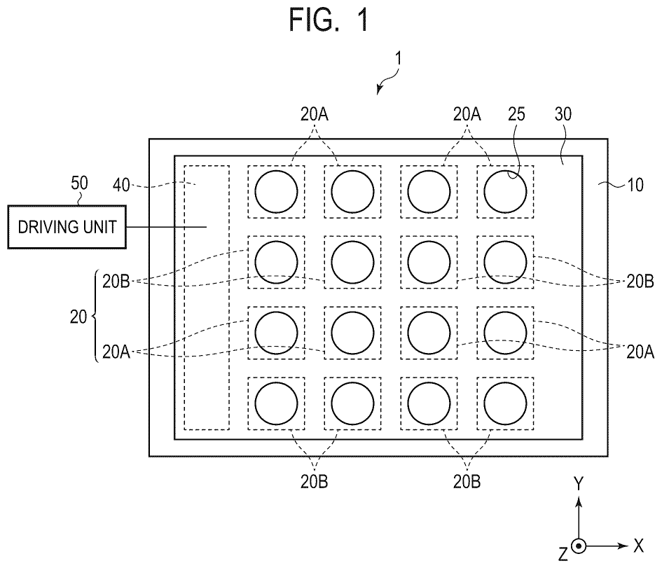

A light emitting device 1 according to one or more embodiments of the present disclosure will be described. FIG. 1 is a plan view of the light emitting device 1 according to the one or more embodiments.

As illustrated in FIG. 1, the light emitting device 1 includes a semiconductor substrate 10, a plurality of light emitting elements 20 (which may include light emitting elements 20A and 20B), an anode wiring 30, a power supply pad 40, and a driving unit 50.

The semiconductor substrate 10 may be formed in a flat plate shape and may include, for example, a GaAs substrate.

The plurality of light emitting elements 20 (e.g., the elements 20A, 20B) may be formed on the common semiconductor substrate 10. The plurality of light emitting elements 20 are vertical cavity surface emitting lasers (VCSELs) having distributed Bragg reflectors (DBRs). The plurality of light emitting elements 20 may be arranged in an array over a plurality of rows and a plurality of columns in one or more embodiments.

In the following description, in a case where the plurality of light emitting elements 20 are arranged in an array, a first direction (row direction) is referred to as an X direction, and a second direction (column direction) is referred to as a Y direction. A direction intersecting the X direction and the Y direction is referred to as a Z direction. The X direction, the Y direction, and the Z direction are typically orthogonal to each other.

The plurality of light emitting elements 20 include light emitting elements 20A and 20B. A reflectance of reflectors of the light emitting elements 20A and 20B may be different from each other. A configuration of the reflectors will be described later. The light emitting elements 20A are provided adjacent to each other in the X direction and constitute an array of one row. The light emitting elements 20B are also provided adjacent to each other in the X direction and constitute an array of one row. The one row array of the light emitting elements 20A and the one row array of the light emitting elements 20B are alternately provided in the Y direction in one or more embodiments.

The anode wiring 30 may include a conductive material such as gold, copper, titanium, or aluminum, and may be connected to an anode electrode of each of the light emitting elements 20A and 20B. The anode wiring 30 may be formed in a planar shape. The anode wiring 30 supplies power from the power supply pad 40 to the light emitting elements 20A and 20B.

The power supply pad 40 may include a conductive material such as copper and may be formed on the semiconductor substrate 10. The power supply pad 40 may be formed integrally with the anode wiring 30. The power supply pad 40 may be connected to the driving unit 50. The power supply pad 40 supplies power from the driving unit 50 to the anode wiring 30.

The driving unit 50 applies drive power to the light emitting elements 20A and 20B. Specifically, the driving unit 50 injects current into the power supply pad 40 and injects the current into each of the anode electrodes of the light emitting elements 20A and 20B via the anode wiring 30. Accordingly, the driving unit 50 can apply the same driving power to the light emitting elements 20A and 20B at the same timing.

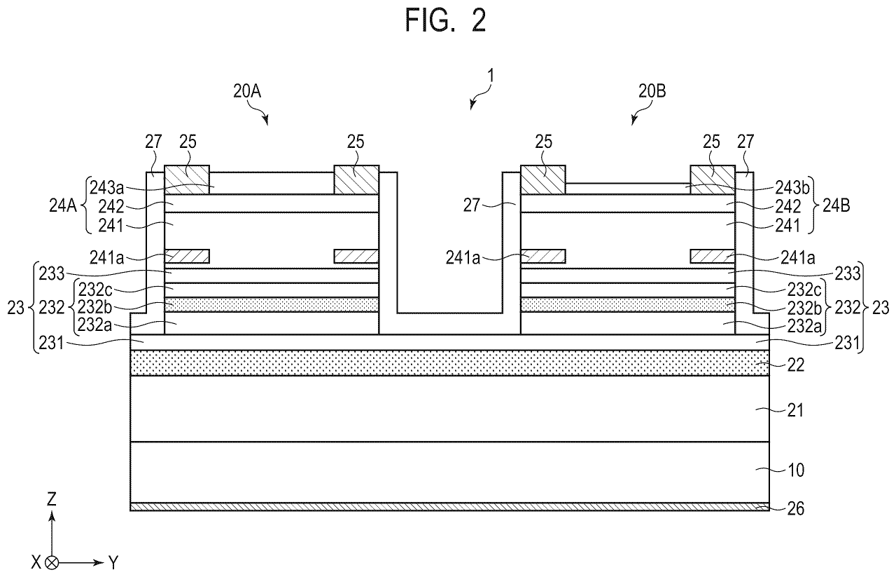

Next, the configuration of the light emitting elements 20A and 20B will be described in detail. FIG. 2 is a cross-sectional view of the light emitting elements 20A and 20B according to one or more embodiments.

The light emitting element 20A may include a semiconductor substrate 10, a lower DBR layer (first reflector) 21, a saturable absorption layer 22, a resonator 23, a reflector (second reflector) 24A, an anode electrode 25, a cathode electrode 26, and an insulating film 27.

The lower DBR layer 21 may be formed on the semiconductor substrate 10. The saturable absorption layer 22 may be formed on the lower DBR layer 21. The resonator 23 may be formed on, over, or adjacent to the saturable absorption layer 22. The reflector 24A may be formed on the resonator 23. The anode electrode 25 may be annularly formed on the reflector 24A. The cathode electrode 26 may be formed on a back surface side of the semiconductor substrate 10 (on the side opposite to the lower DBR layer 21 of the semiconductor substrate 10). The cathode electrode 26 may be connected to a ground.

The lower DBR layer 21 may be formed by, for example, stacking 35 pairs, where each pair is a stacked body including an Al_{0.1}GaAs layer and an Al_{0.9}GaAs layer each having an optical film thickness of ¼λc. Here, λc is a center wavelength of a high reflection band of the lower DBR layer 21, and is, for example, 940 nm in one or more embodiments of the present disclosure.

The saturable absorption layer 22 may include, for example, a multiple quantum well including three layers of a quantum well in which an InGaAs well layer having a thickness of 8 nm is sandwiched by AlGaAs barrier layers having a thickness of 10 nm.

The resonator 23 may include a doped spacer layer 231 formed on the saturable absorption layer 22, a non-doped spacer portion 232 formed on the doped spacer layer 231, and a doped spacer layer 233 formed on the non-doped spacer portion 232.

The non-doped spacer portion 232 may include a non-doped spacer layer 232a formed over the doped spacer layer 231, an active portion 232b formed over the non-doped spacer layer 232a, and a non-doped spacer layer 232c formed over the active portion 232b.

The active portion 232b may include, for example, three active layers. Each of the three active layers may include, for example, a multiple quantum well including four layers of a quantum well in which a InGaAs well layer having a thickness of 8 nm is sandwiched by AlGaAs barrier layers each having a thickness of 10 nm. In this case, the resonator 23 includes a total of twelve quantum wells. The doped spacer layer 231 may include an n-type GaAs layer, the doped spacer layer 233 may include a p-type GaAs layer, and the non-doped spacer layers 232a and 232c may include a non-doped GaAs layer.

As described above, the resonator 23 has a p-i-n junction also existing in a typical VCSEL and has a configuration like a resonator including the active portion 232b in the i layer. However, the number of layers of the quantum wells included in the resonator 23 is larger than the number of layers (about three layers) of the quantum wells included in the typical VCSEL. An effective resonator length of the resonator 23 is 10 μm, which is longer than that of the typical VCSEL. Here, the effective resonator length is a resonator length in which light is sensed in the resonator 23.

The reflector 24A may include an upper DBR layer (reflector) 241 formed on the doped spacer layer 233 of the resonator 23, a contact layer 242 formed on the upper DBR layer 241, and an upper insulating film 243a formed on the contact layer 242.

The upper DBR layer 241 may be formed by, for example, stacking 20 pairs, where each pair is a stacked body including an Al_{0.1}Ga_{0.9}As layer and an Al_{0.9}Ga_{0.1}As layer each having an optical film thickness of ¼λc. An oxidized constriction layer 241a, which is an Al_{0.98}Ga_{0.02}As layer having a thickness of 30 nm, is formed in the upper DBR layer 241.

The oxidized constriction layer 241a can be formed, for example, by oxidizing the Al_{0.98}Ga_{0.02}As layer from a side surface of a mesa with water vapor at the time of manufacturing. The oxidized constriction layer 241a has a non-oxidized portion in a center of the mesa and an oxidized portion in a vicinity of a sidewall of the mesa. A diameter of the non-oxidized portion in plan view may be about 10 μm. As a result, since the current injected into the light emitting element 20A flows only in the non-oxidized portion, causing laser oscillation only in an area that overlaps the center of the mesa in plan view.

The contact layer 242 is located between the anode electrode 25 and the upper DBR layer 241 to improve electrical contact between the anode electrode 25 and the upper DBR layer 241.

The upper insulating film 243a is formed in a thin film shape and insulates the contact layer 242 in a state where a part of a surface of the anode electrode 25 is exposed.

In the light emitting element 20A described above, the non-doped spacer portion 232 of the resonator 23, the doped spacer layer 233 of the resonator 23, and the reflector 24A are formed in a mesa shape. An insulating film 27 is formed on a side surface of the mesa, and the insulating film 27 insulates the non-doped spacer portion 232, the doped spacer layer 233, and the reflector 24A. The insulating film 27 is formed on the doped spacer layer 231 between the mesas to insulate the doped spacer layer 231 between the mesas.

As described above, the light emitting element 20A capable of generating pulse a light having a high peak value, and a short pulse width is realized by introducing the saturable absorption layer 22 based on the configuration of the typical VCSEL. Further, although an active layer of the typical VCSEL includes three quantum wells, a volume of the active portion 232b is increased by increasing the number of quantum wells to twelve layers. Further, the effective resonator length of the resonator 23 is extended. Thus, the light emitting element 20A realizes a VCSEL capable of emitting a more effective high peak value pulse light.

In one or more embodiments, the following three elements are further added based on the configuration of the typical VCSEL. The first of the three elements added to the VCSEL is to substantially increase the volume of the active layer. For example, the typical VCSEL includes three quantum wells, but in one or more embodiments, the volume of the active layer may be increased. The second is to introduce the saturable absorption layer. The third is to extend the effective resonator length as the VCSEL. The effective resonator length is a resonator length in which light is sensed in the resonator. More specifically, the effective resonator length is an average value of a distance in which the light transmitted through the active layer in the resonant direction is reflected by the two mirrors constituting the resonator, and the light propagates until the light transmits through the active layer again. By adding at least one of these elements, preferably three, it is possible to realize the VCSEL capable of generating a light pulse with the high peak value and the short pulse width.

Next, the light emitting element 20B will be described. The light emitting element 20B has the same configuration as the light emitting element 20A except that a thickness of an upper insulating film 243b is different from that of the light emitting element 20A.

Regarding the light emitting element 20B, differences from the light emitting element 20A will be described in detail, and description of the same configuration will be omitted as appropriate.

The light emitting element 20B includes a semiconductor substrate 10, a lower DBR layer 21, a saturable absorption layer 22, a resonator 23, a reflector 24B, an anode electrode 25, a cathode electrode 26, and an insulating film 27.

The reflector 24B may include an upper DBR layer 241 formed on the doped spacer layer 233 of the resonator 23, a contact layer 242 formed on the upper DBR layer 241, and an upper insulating film 243b formed on the contact layer 242.

The upper insulating film 243b is formed in a thin film shape and insulates the contact layer 242 in a state where a part of a surface of the anode electrode 25 is exposed. A thickness of the upper insulating film 243b in the Z direction is different from a thickness of the upper insulating film 243a in the Z direction. Here, the thickness of the upper insulating film 243b in the Z direction is formed to be thinner than the thickness of the upper insulating film 243a in the Z direction. The upper insulating film 243b may be formed, for example, by a method of forming the upper insulating film to be thinner than the upper insulating film 243a by partially removing the upper insulating film by etching, or a method of forming the upper insulating film to be thinner than the upper insulating film 243a in a film forming process. In this way, a reflectance of the reflectors 24A and 24B is different by making the thickness of the upper insulating film different, and light emitting timings of the light emitting elements 20A and 20B are shifted. Hereinafter, the light emission timings of the light emitting elements 20A and 20B will be described.

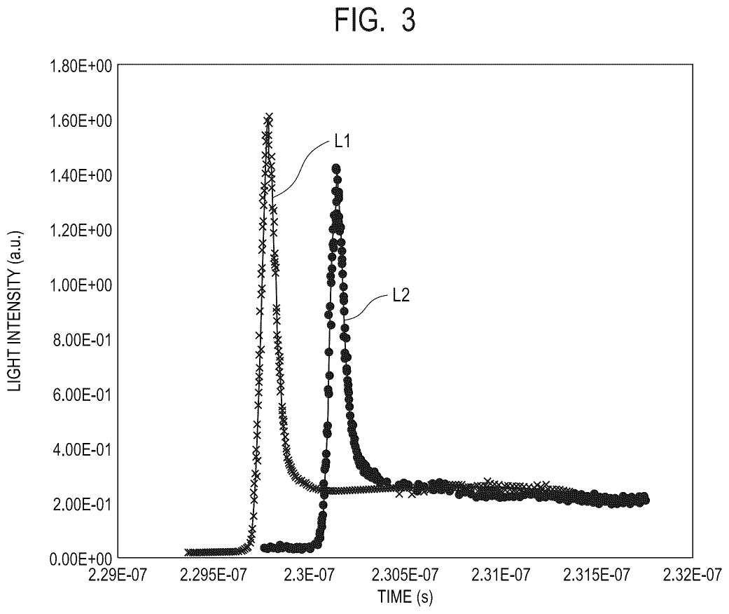

FIG. 3 is a diagram illustrating a waveform of high peak value pulse light according to one or more embodiments of the present disclosure. In FIG. 3, a vertical axis represents light intensity, and a horizontal axis represents time. FIG. 3 illustrates a high peak value pulse light L1 emitted from the light emitting element 20A and a high peak value pulse light L2 emitted from the light emitting element 20B. The full width at half maximum of the high peak value pulse lights L1 and L2 is 50 ps to 500 ps, and is typically about 100 ps. Although the same drive voltage is applied to each of the light emitting elements 20A and 20B at the same timing, as illustrated in FIG. 3, an emission timing of the high peak value pulse light L1 and an emission timing of the high peak value pulse light L2 are shifted from each other. Specifically, the emission timing of the high peak value pulse light L2 is delayed by about 400 ps from the emission timing of the high peak value pulse light L1. This is because the thickness of the upper insulating film 243b of the light emitting element 20B is thinner than the thickness of the upper insulating film 243a of the light emitting element 20A. Accordingly, the reflectance of the reflector 24B of the light emitting element 20B is smaller than the reflectance of the reflector 24A of the light emitting element 20A. Specifically, the reflectance of the reflector 24B of the light emitting element 20B is 98.0%, and the reflectance of the reflector 24A of the light emitting element 20A is 99.1%. The light intensity of the high peak value pulse light L2 is slightly smaller (about 85%) than the light intensity of the high peak value pulse light L1. However, the light intensity of 80% or more is maintained.

Although the reflectance of the reflector is reduced by reducing the thickness of the upper insulating film in one or more embodiments, the reflectance is generally determined by the relationship with an optical thickness, and therefore, the reflectance is not necessarily reduced by reducing the thickness of the upper insulating film. Increasing the thickness of the upper insulating film may also reduce the reflectance. The thickness of the upper insulating film is appropriately adjusted so that the reflectance becomes a target value.

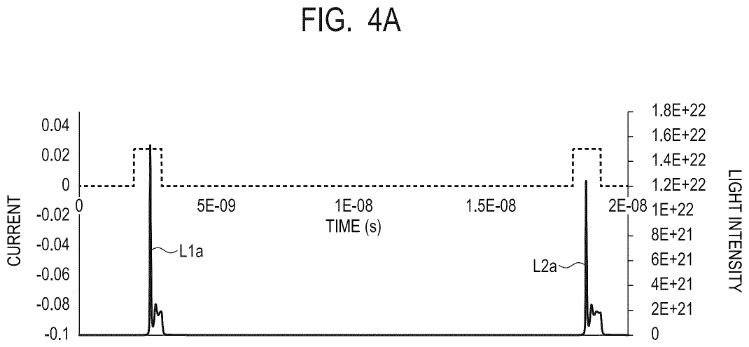

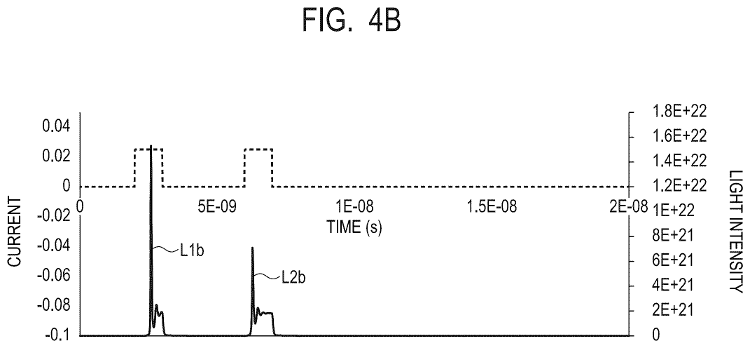

FIGS. 4A and 4B are diagrams illustrating the relationship between light intensity and an emission interval of the high peak value pulse light by the VCSEL according to the comparative example. FIG. 4A illustrates the light intensity of the high peak value pulse light when the emission interval between the first high peak value pulse light L1a and the second high peak value pulse light L2a is 15 ns. FIG. 4B illustrates the light intensity of the high peak value pulse light when the emission interval between the first high peak value pulse light L1b and the second high peak value pulse light L2b is 3 ns. FIGS. 4A and 4B also illustrate current waveforms injected into the VCSEL.

As illustrated in FIG. 4A, when the high peak value pulse light is emitted at an interval of 15 ns, the light intensity of the high peak value pulse light L2a is slightly smaller (about 80%) than the light intensity of the high peak value pulse light L1a. In this case, since the light intensity of 80% or more is maintained, there is no problem.

On the other hand, as illustrated in FIG. 4B, when the high peak value pulse light is emitted at intervals of 3 ns, the light intensity of the high peak value pulse light L2b is significantly smaller (about 50%) than the light intensity of the high peak value pulse light L1b. This is because the emission interval between the high peak value pulse light L1b and the high peak value pulse light L2b is short, and thus the high peak value pulse light L2b is emitted in a state where carriers remain in the saturable absorption layer.

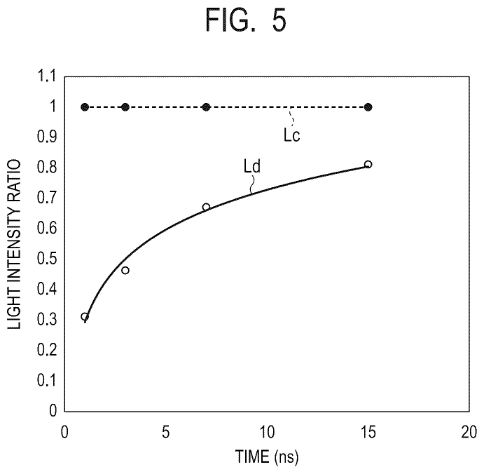

FIG. 5 is a diagram illustrating a relationship between an emission interval and light intensity ratio in a normal pulse light Lc and the high peak value pulse light Ld according to a comparative example. Here, the normal pulse light Lc has a smaller peak (approximately ¼) than the high peak value pulse light Ld. In FIG. 5, a vertical axis represents a ratio of the light intensity of the second high peak value pulse light Ld (normal pulse light Lc) to the light intensity of the first high peak value pulse light Ld (normal pulse light Lc), and a horizontal axis represents an emission interval.

As illustrated in FIG. 5, the ratio of the light intensity of the second normal pulse light Lc to the light intensity of the first normal pulse light Lc is “1” regardless of the emission interval.

On the other hand, the ratio of the light intensity of the second high peak value pulse light Ld to the light intensity of the first high peak value pulse light Ld becomes smaller as the emission interval becomes shorter.

For example, when the emission interval is 15 ns, the light intensity ratio is about 80%, but when the emission interval is 3 ns, the light intensity ratio is about 50%. Therefore, in the VCSEL according to the comparative example, it is necessary to provide the emission interval of 15 ns or more, and it is difficult to repeatedly emit the high peak value pulse light Ld in a short time.

In contrast, according to the light emitting device 1 of one or more embodiments, the reflectance of the reflector 24A and the reflectance of the reflector 24B are different from each other. With this configuration, when the drive voltage is applied to the light emitting elements 20A and 20B at the same timing, the light emitting elements 20A and 20B emit pulse lights at different timings. Accordingly, the light emitting device 1 can emit the high peak value pulse light L1 emitted from the light emitting element 20A and the high peak value pulse light L2 emitted from the light emitting element 20B at short intervals. Then, the driving unit 50 repeatedly outputs the drive voltage to be applied to the light emitting elements 20A and 20B at the same timing at constant intervals, so that the light emitting device 1 can repeatedly emit the high peak value pulse light at short intervals.

Next, a light emitting device 1A according to one or more embodiments will be described. In the following one or more embodiment examples, the same components as those of the light emitting device 1 according to the aforementioned one or more embodiments are denoted by the same reference numerals, and a detailed description thereof will be appropriately omitted.

The light emitting device 1A is different from the light emitting device 1 according to the aforementioned one or more embodiments in that the number of pairs of the stacked body constituting the upper DBR layer is different between the two light emitting elements. Hereinafter, differences from the aforementioned one or more embodiments will be mainly described.

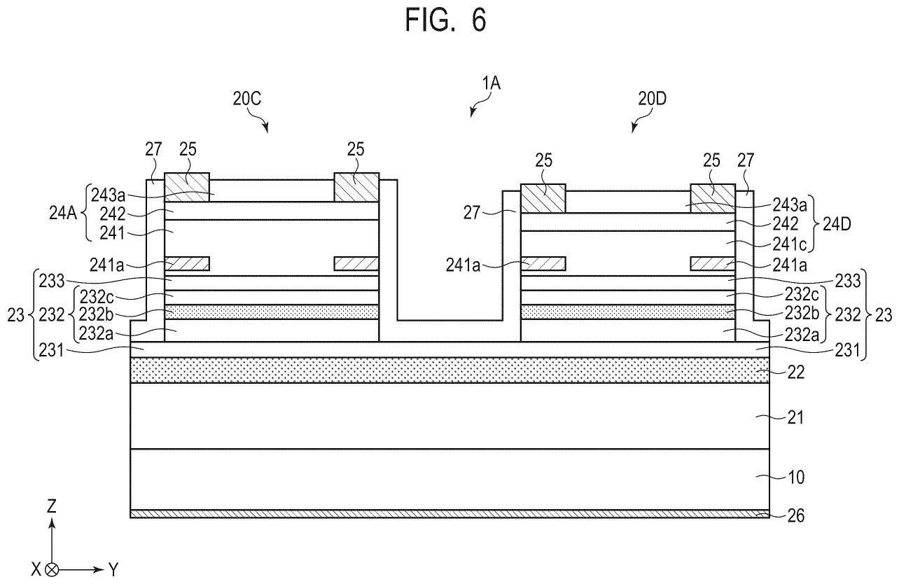

FIG. 6 is a cross-sectional view of the light emitting elements 20C and 20D according to one or more embodiments of the present disclosure. The light emitting element 20C has the same configuration as the light emitting element 20A.

The light emitting element 20D includes a semiconductor substrate 10, a lower DBR layer 21, a saturable absorption layer 22, a resonator 23, a reflector 24D, an anode electrode 25, a cathode electrode 26, and an insulating film 27.

The reflector 24D may include an upper DBR layer 241c formed on the doped spacer layer 233 of the resonator 23, a contact layer 242 formed on the upper DBR layer 241c, and an upper insulating film 243a formed on the contact layer 242.

For example, a stacked body including an Al_{0.1}Ga_{0.9}As layer and an Al_{0.9}Ga_{0.1}As layer each having an optical film thickness of ¼λc is formed as one pair. The number of pairs of the stacked body of the upper DBR layer 241c is different from the number of pairs of the stacked body of the upper DBR layer 241 of the light emitting element 20C. Here, the number of pairs of the stacked body of the upper DBR layer 241c is smaller than the number of pairs of the stacked body of the upper DBR layer 241 of the light emitting element 20C. When the number of pairs of the upper DBR layer 241c is formed to be small, there are a method of removing a part by etching and a method of regrowing only a part of an epitaxial layers other than the upper DBR layer 241c. Accordingly, the reflectance of the reflector 24D of the light emitting element 20D is smaller than the reflectance of the reflector 24A of the light emitting element 20C. Therefore, an emission timing of the high peak value pulse light emitted from the light emitting element 20D becomes later than an emission timing of the high peak value pulse light emitted from the light emitting element 20C.

As described above, the light emitting device 1A includes the upper DBR layers 241 and 241c each including a plurality of semiconductor layer pairs each including two semiconductor layers having different refractive indices. The number of pairs of semiconductor layers of the upper DBR layer 241 of the light emitting element 20C and the number of pairs of semiconductor layers of the upper DBR layer 241c of the light emitting element 20D are different from each other. With this configuration, the light emitting device 1A can shift the emission timing of the high peak value pulse light emitted from each of the light emitting elements 20C and 20D, and as a result, the high peak value pulse light can be emitted at short intervals.

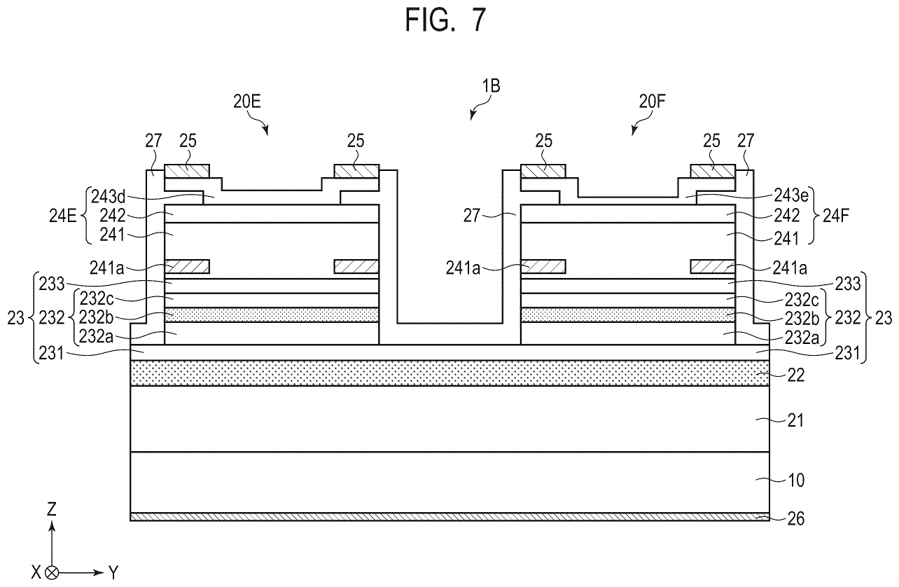

Next, a light emitting device 1B according to one or more embodiments of the present disclosure will be described. FIG. 7 is a cross-sectional view of light emitting elements 20E and 20F according to one or more embodiments.

The light emitting element 20E is different from the light emitting element 20A in that a transparent conductive film (for example, ITO: Indium Tin Oxide) 243d is provided instead of the upper insulating film 243a and has the same configuration as the light emitting element 20A in other respects. Regarding the light emitting element 20E, differences from the light emitting element 20A will be described in detail, and description of the same configuration will be omitted as appropriate.

The light emitting element 20E includes a semiconductor substrate 10, a lower DBR layer 21, a saturable absorption layer 22, a resonator 23, a reflector 24E, an anode electrode 25, a cathode electrode 26, and an insulating film 27.

The reflector 24E may include an upper DBR layer 241 formed on the doped spacer layer 233 of the resonator 23, a contact layer 242 formed on the upper DBR layer 241, and a transparent conductive film 243d formed on the contact layer 242.

The anode electrode 25 is formed on the transparent conductive film 243d. The transparent conductive film 243d allows current injected into the anode electrode 25 to flow to a center of the upper DBR layer 241 via the contact layer 242.

Next, the light emitting element 20F will be described. The light emitting element 20F has the same structure as the light emitting element 20E except that a thickness of a transparent conductive film 243e is different from that of the light emitting element 20E.

Regarding the light emitting element 20F, differences from the light emitting element 20E will be described in detail, and description of the same configuration will be omitted as appropriate.

The light emitting element 20F includes a semiconductor substrate 10, a lower DBR layer 21, a saturable absorption layer 22, a resonator 23, a reflector 24F, an anode electrode 25, a cathode electrode 26, and an insulating film 27.

The reflector 24F may include an upper DBR layer 241 formed on the doped spacer layer 233 of the resonator 23, a contact layer 242 formed on the upper DBR layer 241, and a transparent conductive film 243e formed on the contact layer 242.

The anode electrode 25 is formed on the transparent conductive film 243e. The transparent conductive film 243e allows current injected into the anode electrode 25 to flow to a center of the upper DBR layer 241 via the contact layer 242.

A thickness of the center of the transparent conductive film 243e is different from a thickness of the center of the transparent conductive film 243d. Here, the thickness of the center of the transparent conductive film 243e is thinner than the thickness of the center of the transparent conductive film 243d. The transparent conductive film 243e may be formed, for example, the transparent conductive film is partially removed by, for example, etching to be thinner than the transparent conductive film 243d. Accordingly, the reflectance of the reflector 24F of the light emitting element 20F is smaller than the reflectance of the reflector 24E of the light emitting element 20E. Therefore, an emission timing of the high peak value pulse light emitted from the light emitting element 20F becomes later than an emission timing of the high peak value pulse light emitted from the light emitting element 20E.

As described above, according to the light emitting device 1B, the thickness of the transparent conductive film 243d of the light emitting element 20E and the thickness of the transparent conductive film 243e of the light emitting element 20F are different from each other. According to this configuration, the light emitting device 1B can shift the emission timing of the high peak value pulse lights emitted from each of the light emitting elements 20E and 20F, and as a result, the high peak value pulse light can be emitted at short intervals.

Although an example in which the transparent conductive film is provided instead of the upper insulating film 243a of one or more of the aforementioned embodiments has been described in one or more additional embodiments, the one or more additional embodiments are not limited thereto, and the transparent conductive film 243d may be provided between the upper insulating film 243a and the contact layer 242.

Next, a light emitting device 1C according to one or more embodiments of the present disclosure will be described. The light emitting device 1C differs from the other aforementioned one or more embodiments in that a light emitting timing is shifted by changing drive voltage applied to a light emitting element 20G.

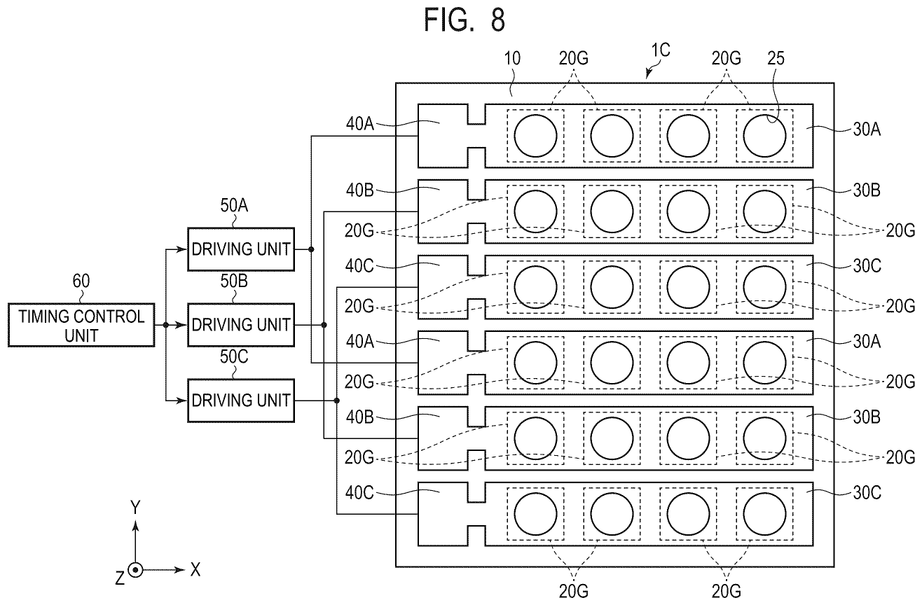

FIG. 8 is a plan view of the light emitting device 1C according to one or more embodiments of the present disclosure.

As illustrated in FIG. 8, the light emitting device 1C includes a semiconductor substrate 10, a plurality of light emitting elements 20G, anode wirings 30A, 30B, and 30C, power supply pads 40A, 40B, and 40C, driving units 50A, 50B, and 50C, and a timing control unit 60.

In the semiconductor substrate 10, the light emitting elements 20G are arranged in an array over a plurality of rows and a plurality of columns. That is, the light emitting elements 20G are arranged in an array over the X direction and the Y direction.

Each of the anode wirings 30A, 30B, and 30C extends in the X direction and is provided adjacent to each other in the Y direction. Here, a total of six anode wirings are arranged in the Y direction in the order of the anode wirings 30A, 30B, and 30C. The anode wiring 30A is connected to a plurality of light emitting elements 20G along the X direction, the anode wiring 30B is connected to other light emitting elements 20G along the X direction, and the anode wiring 30C is connected to other light emitting elements 20G along the X direction.

The power supply pad 40A is connected to the anode wiring 30A, the power supply pad 40B is connected to the anode wiring 30B, and the power supply pad 40C is connected to the anode wiring 30C. Each of the power supply pads 40A, 40B, and 40C is connected to a corresponding driving unit. Here, the power supply pad 40A is connected to the driving unit 50A, the power supply pad 40B is connected to the driving unit 50B, and the power supply pad 40C is connected to the driving unit 50C. The power supply pad 40A supplies power from the driving unit 50A to the light emitting element 20G connected to the anode wiring 30A.

The power supply pad 40B supplies power from the driving unit 50B to the light emitting element 20G connected to the anode wiring 30B. The power supply pad 40C supplies power from the driving unit 50C to the light emitting element 20G connected to the anode wiring 30C.

Each of the driving units 50A, 50B, and 50C applies different drive voltage to the target light emitting element 20G at the same timing. Specifically, the driving unit 50A applies drive voltage (for example, 5.0 V) to the light emitting element 20G connected to the anode wiring 30A. The driving unit 50B applies drive voltage (for example, 4.5 V) to the light emitting element 20G connected to the anode wiring 30B. The driving unit 50C applies drive voltage (for example, 4.0 V) to the light emitting element 20G connected to the anode wiring 30C.

The timing control unit 60 controls drive timings of the driving units 50A, 50B, and 50C. Specifically, the timing control unit 60 controls to apply the different drive voltages to the driving units 50A, 50B, and 50C at the same timing.

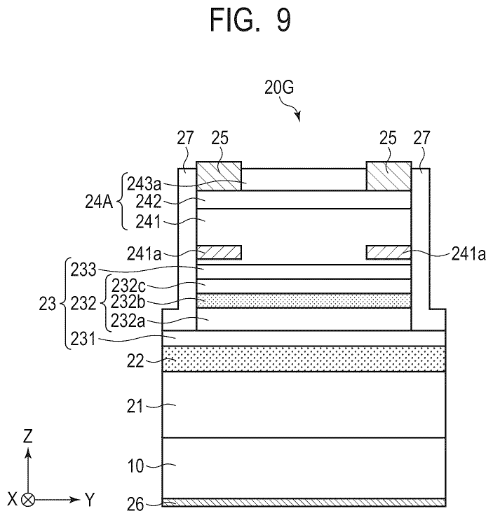

FIG. 9 is a cross-sectional view of the light emitting element 20G according to one or more embodiments of the present disclosure. The light emitting element 20G has the same configuration as the light emitting element 20A illustrated in FIG. 2. The light emitting device 1C includes the light emitting elements 20G that all have the same configuration.

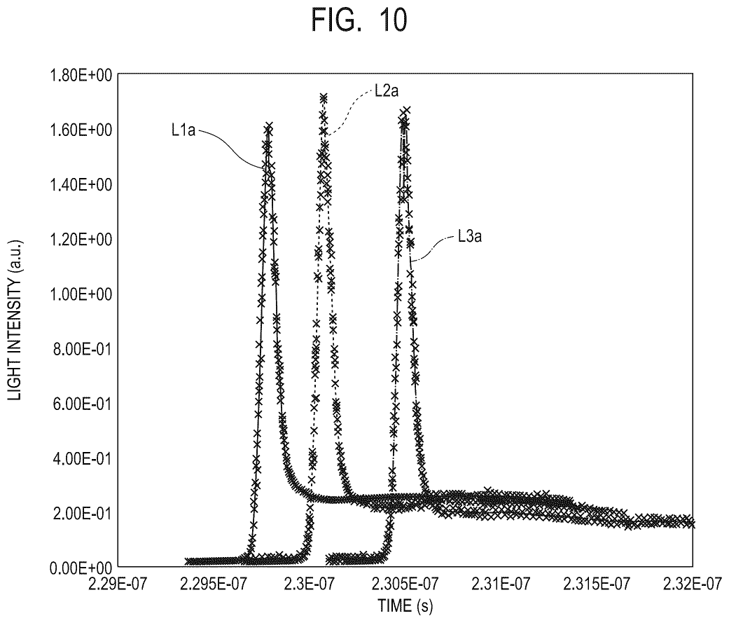

FIG. 10 is a diagram illustrating a waveform of high peak value pulse light according to one or more additional embodiments. In FIG. 10, a vertical axis represents light intensity, and a horizontal axis represents time. FIG. 10 illustrates three high peak value pulse lights L1a, L2a, and L3a having different emission timings.

The high peak value pulse light L1a is emitted from the light emitting element 20G driven by the driving unit 50A. The high peak value pulse light L2a is emitted from the light emitting element 20G driven by the driving unit 50B. The high peak value pulse light L3a is emitted from the light emitting element 20G driven by the driving unit 50C.

A full width at half maximum of the high peak value pulse light L1a, L2a, and L3a is about 100 ps. Although the drive voltage is applied to each of the light emitting elements 20G at the same timing, the emission timings of the high peak value pulse lights L1a, L2a, and L3a are shifted from each other as illustrated in FIG. 10. Specifically, the emission timing of the high peak value pulse light L2a is delayed by about 300 ps from the emission timing of the high peak value pulse light L1a. The emission timing of the high peak value pulse light L3a is delayed by about 400 ps from the emission timing of the high peak value pulse light L2a. This is because the drive voltage applied to the light emitting element 20G is changed by the driving units 50A, 50B, and 50C. As the drive voltage decreases, the emission timing of the high peak value pulse light is delayed.

As described above, according to the light emitting device 1C, the drive voltage applied to the light emitting element 20G is changed. With this configuration, the light emitting device 1C can shift the emission timing of the high peak value pulse light emitted from the light emitting element 20G for each drive voltage, and as a result, the high peak value pulse light can be emitted at short intervals.

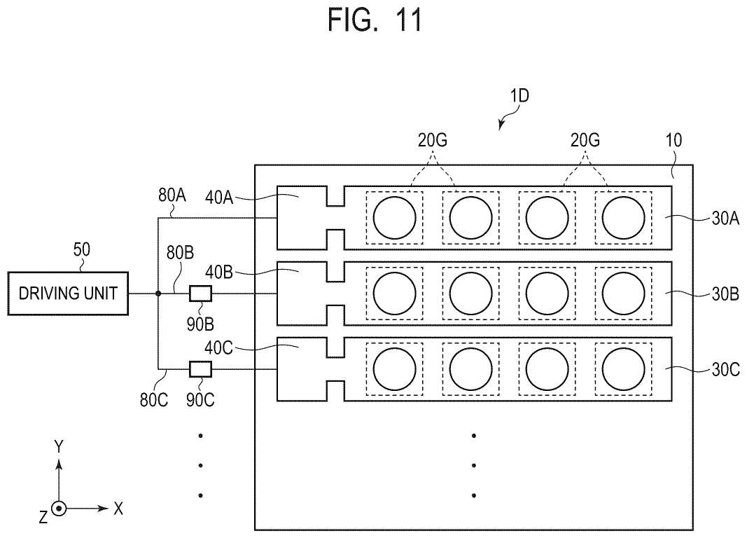

FIG. 11 is a block diagram of a light emitting device 1D according to one or more embodiments of the present disclosure. FIG. 11 illustrates a part of the light emitting device 1D. The light emitting device 1D is different from the light emitting device 1C according to the aforementioned one or more embodiments (shown, for example, in at least FIG. 8) in that the drive voltage applied to the light emitting element 20G is changed by a voltage drop component.

As illustrated in FIG. 11, the light emitting device 1D includes a semiconductor substrate 10, a plurality of light emitting elements 20G, anode wirings 30A, 30B, and 30C, power supply pads 40A, 40B, and 40C, a driving unit 50, paths 80A, 80B, and 80C, and voltage drop components 90B and 90C.

The paths 80A, 80B, and 80C are wirings that connect the driving unit 50 and the power supply pads. Specifically, the path 80A connects the driving unit 50 and the power supply pad 40A, the path 80B connects the driving unit 50 and the power supply pad 40B, and the path 80C connects the driving unit 50 and the power supply pad 40C.

The voltage drop components 90B and 90C are configured to reduce voltage, and may be, for example, a wiring circuit including a resistor element and a long wiring. Resistance values of the voltage drop components 90B and 90C are different from each other, and here, the resistance value of the voltage drop component 90B is smaller than the resistance value of the voltage drop component 90C. The voltage drop components 90B and 90C are provided outside the semiconductor substrate 10. The voltage drop component 90B is provided on the path 80B, and the voltage drop component 90C is provided on the path 80C.

The driving unit 50 applies the same drive voltage to each of the paths 80A, 80B, and 80C. Thus, the highest drive voltage is applied to the light emitting element 20G to which current is injected through the path 80A. The second highest drive voltage is applied to the light emitting element 20G to which current is injected through the path 80B and the voltage drop component 90B. The lowest drive voltage is applied to the light emitting element 20G to which current is injected through the path 80C and the voltage drop component 90C.

As described above, the light emitting device 1D includes the voltage drop components 90B and 90C provided on the path between the driving unit 50 and the light emitting element 20G. With this configuration, the light emitting device 1D can change the drive voltage applied to the light emitting element 20G. Accordingly, the light emitting device 1D can shift the emission timing of the high peak value pulse light emitted from the light emitting element 20G for each drive voltage, and as a result, the high peak value pulse light can be emitted at short intervals. Although the voltage drop component 90B is disposed between the driving unit 50 and the power supply pad 40B in one or more embodiments, the voltage drop component 90B may be disposed between the power supply pad 40B and the anode wiring 30B in one or more other embodiments of the present disclosure. Similarly, the voltage drop component 90C may be disposed between the power supply pad 40C and the anode wiring 30C.

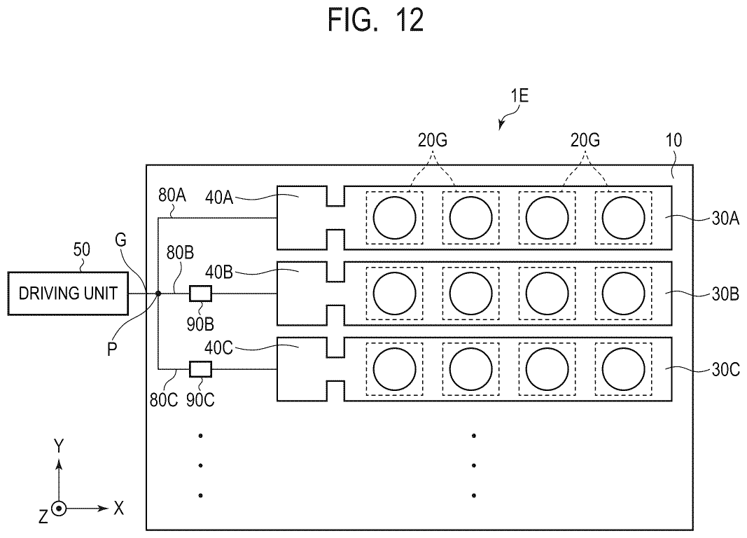

FIG. 12 is a block diagram of a light emitting device 1E according to one or more embodiments of the present disclosure. FIG. 12 illustrates a part of the light emitting device 1E. The light emitting device 1E is different from the light emitting device 1D according to one or more of the aforementioned embodiments (shown, for example, in FIG. 11) in that the voltage drop components 90B and 90C are formed in the semiconductor substrate 10.

The paths 80A, 80B, and 80C branch at a branch point P of the semiconductor substrate 10, and the branch destination is connected to the target power supply pad. The branch point P is connected to an external connection G. The external connection G is connected to the driving unit 50. According to the light emitting device 1E, the external connection G can be integrated into one.

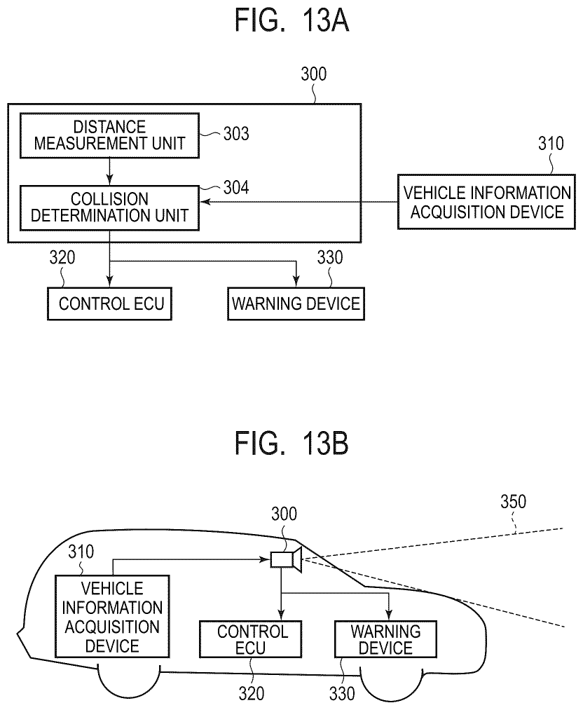

Next, a movable body according to one or more embodiments of the present disclosure will be described with reference to FIG. 13A and FIG. 13B. FIG. 13A and FIG. 13B are block diagrams of an imaging system and a movable body according to one or more embodiments.

FIG. 13A illustrates a configuration example of equipment mounted on a vehicle as an in-vehicle camera. The device 300 includes a distance measurement unit (such as, for example, Light Detection and Ranging (LiDAR)) 303 that measures a distance to a measurement target, and a collision determination unit 304 that determines whether there is a possibility of collision based on the distance measured by the distance measurement unit 303. The distance measurement unit 303 includes the light emitting device described in the one or more aforementioned embodiments, a light receiving device having a light receiving element, and a distance information acquisition unit. The distance information acquisition unit acquires information on a distance to the measurement target based on a time difference between a timing at which light is emitted from the light emitting element and a timing at which the light receiving element receives light emitted from the light emitting element and reflected by the measurement target.

The device 300 is connected to the vehicle information acquisition device 310 and can acquire vehicle information such as a vehicle speed, a yaw rate, and a steering angle. In addition, a control ECU 320, which is a control device that outputs a control signal for generating braking force to the vehicle based on a determination result of the collision determination unit 304, is connected to the device 300. The device 300 is also connected to a warning device 330 that issues a warning to a driver based on the determination result of the collision determination unit 304. For example, when the determination result of the collision determination unit 304 indicates that a possibility of collision is high, the control ECU 320 performs vehicle control to avoid collision and reduce damage by applying a brake, returning an accelerator, suppressing engine output, or the like. The warning device 330 gives the warning to the user by sounding a warning such as a sound, displaying warning information on a screen of a car navigation system or the like, giving vibration to a seat belt or a steering wheel, or the like. These devices of the device 300 function as a movable body control unit that controls an operation of controlling the vehicle as described above.

In one or more embodiments, the distance to the surroundings of the vehicle, for example, a front or a rear is measured by the device 300. FIG. 13B illustrates the device 300 in a case where distance measurement is performed in front of the vehicle (distance measurement range 350). The vehicle information acquisition device 310 serving as the distance measurement control unit sends an instruction to the device 300 or the distance measurement unit 303 to perform the distance measurement operation. With such a configuration, the accuracy of distance measurement can be further improved.

In the above description, an example in which control is performed so as not to collide with another vehicle has been described, but the present invention is also applicable to control in which automatic driving is performed to follow another vehicle, control in which automatic driving is performed so as not to protrude from a lane, and the like. Furthermore, the device is not limited to vehicles such as automobiles, and can be applied to, for example, ships, aircrafts, artificial satellites, industrial robots, consumer robots, and the like movable body (mobile devices). In addition, the present invention is not limited to the movable body and can be widely applied to devices utilizing object recognition or biological recognition, such as an intelligent traffic system (ITS) and a monitoring system.

### One or More Additional Features of One or More Embodiments

The features of the present disclosure are not limited to the above-described embodiments, and various modifications are possible. For example, an example in which a part of the configuration of any of the embodiments is added to another embodiment or an example in which a part of the configuration of another embodiment is replaced with another embodiment is also an embodiment of the present disclosure.

For example, the cathode electrode 26 is provided on the lower surface of the semiconductor substrate 10 but is not limited to this. For example, the cathode electrode 26 may be provided to be electrically connected to the doped spacer layer 231.

Although the saturable absorption layer 22 and the resonator 23 have been described as separate constituent elements, the present invention is not limited thereto, and for example, both the resonator 23 and the saturable absorption layer 22 may be resonators.

The number of the light emitting elements constituting the array is not limited to the example described above. The types of the light emitting elements having different reflectance and the pattern of the drive voltage are not limited to the examples described above.

In the above description, the mesa is formed up to the upper part of the doped spacer layer 231, but is not limited thereto, and may be formed up to the lower part of the oxidized constriction layer 241a, for example. The mesa is preferably formed above the saturable absorption layer 22. This is because non-emitting recombination increases in the saturable absorption layer 22 due to the mesa formation.

According to one or more features of the present disclosure, it is possible to realize the light emitting device and the ranging device capable of emitting high peak value pulse light at short intervals.

While one or more features of the present disclosure have been described with reference to one or more embodiments, it is to be understood that the scope of the present disclosure is not limited to the disclosed one or more embodiments. The scope of the following claims is to be accorded the broadest interpretation to encompass all such modifications and equivalent structures and functions.

This application claims the benefit of Japanese Patent Application No. 2024-079726, filed May 15, 2024, which is hereby incorporated by reference herein in its entirety.

What is claimed is:

1. A light emitting device comprising:
a first light emitting element and a second light emitting element formed on a common semiconductor substrate; and
a driving unit that operates to apply drive voltage to each of the first light emitting element and the second light emitting element,
wherein each of the first light emitting element and the second light emitting element includes:
a first reflector formed on the semiconductor substrate,
a resonator formed on the first reflector and the resonator being disposed on or adjacent to a saturable absorption layer, and
a second reflector formed on the resonator, and
wherein, in a case where the drive voltage is applied to each of the first light emitting element and the second light emitting element at the same timing, the first light emitting element and the second light emitting element respectively emit a pulse light at different timings.

2. The light emitting device according to claim 1, wherein a reflectance of the second reflector of the first light emitting element and a reflectance of the second reflector of the second light emitting element are different from each other.

3. The light emitting device according to claim 2,
wherein the second reflector includes a mirror and an insulating film formed on the mirror, and
wherein a thickness of the insulating film of the first light emitting element and a thickness of the insulating film of the second light emitting element are different from each other.

4. The light emitting device according to claim 2,
wherein the second reflector includes a plurality of pairs of semiconductor layers, each of the pairs of the semiconductor layers includes two semiconductor layers having different refractive indices from each other, and
wherein the number of pairs of the semiconductor layers of the second reflector of the first light emitting element and the number of pairs of the semiconductor layers of the second reflector of the second light emitting element are different from each other.

5. The light emitting device according to claim 2,
wherein each of the second reflectors includes a mirror and a transparent conductive film formed on the mirror, and
wherein a thickness of the transparent conductive film of the first light emitting element and a thickness of the transparent conductive film of the second light emitting element are different from each other.

6. The light emitting device according to claim 2, wherein the drive voltage applied to the first light emitting element and the drive voltage applied to the second light emitting element are the same as each other.

7. The light emitting device according to claim 1, wherein the drive voltage applied to the first light emitting device and the drive voltage applied to the second light emitting device are different from each other.

8. The light emitting device according to claim 7,
wherein the driving unit includes:
a first driving unit configured to apply the drive voltage to the first light emitting element, and
a second driving unit configured to apply the drive voltage different from the drive voltage applied to the first light emitting element to the second light emitting element.

9. The light emitting device according to claim 7, further comprising a voltage drop component provided on a path between the driving unit and either the first light emitting element or the second light emitting element.

10. The light emitting device according to claim 9, wherein the voltage drop component is formed on the semiconductor substrate.

11. The light emitting device according to claim 9, wherein the voltage drop component is provided outside the semiconductor substrate.

12. The light emitting device according to claim 7, wherein a reflectance of the second reflector of the first light emitting element and a reflectance of the second reflector of the second light emitting element are the same as each other.

13. The light emitting device according to claim 1, wherein the driving unit outputs at constant intervals and repeatedly the drive voltage that are applied at the same timing to each of the first light emitting element and the second light emitting element.

14. The light emitting device according to claim 1, wherein a full width at half maximum of the pulse light is 50 ps to 500 ps.

15. A light emitting device comprising:
a first light emitting element and a second light emitting element formed on a common semiconductor substrate; and
a driving unit that operates to apply drive voltage to each of the first light emitting element and the second light emitting element,
wherein each of the first light emitting element and the second light emitting element includes:
a first reflector formed on the semiconductor substrate,
a resonator formed on the first reflector and the resonator being disposed on or adjacent to a saturable absorption layer, and
a second reflector formed on the resonator,
wherein a reflectance of the second reflector of the first light emitting element and a reflectance of the second reflector of the second light emitting element are different, and
wherein, in a case where the drive voltage is applied to each of the first light emitting element and the second light emitting element at the same timing, the first light emitting element and the second light emitting element respectively emit a pulse light at different timings.

16. A light emitting device comprising:
a first light emitting element and a second light emitting element formed on a common semiconductor substrate; and
a driving unit that operates to apply drive voltage to each of the first light emitting element and the second light emitting element,
wherein each of the first light emitting element and the second light emitting element includes:
a first reflector formed on the semiconductor substrate,
a resonator formed on the first reflector and the resonator being disposed on or adjacent to a saturable absorption layer, and
a second reflector formed on the resonator,
wherein the drive voltage applied to the first light emitting device and the drive voltage applied to the second light emitting device are different from each other, and
wherein, in a case where the drive voltage is applied to each of the first light emitting element and the second light emitting element at the same timing, the first light emitting element and the second light emitting element respectively emit a pulse light at different timings.

17. A ranging device comprising:
the light emitting device according to claim 1;
a light receiving device that operates to receive light emitted from the light emitting device and reflected by a measurement target; and
a distance information acquisition unit that operates to acquire information on a distance to the measurement target based on a time difference between a timing at which light is emitted from the light emitting device and a timing at which the light receiving device receives light.

18. A movable body comprising:
a ranging device including:
(i) the light emitting device according to claim 1;
(ii) a light receiving device that operates to receive light emitted from the light emitting device and reflected by a measurement target; and
(iii) a distance information acquisition unit that operates to acquire information on a distance to the measurement target based on a time difference between a timing at which light is emitted from the light emitting device and a timing at which the light receiving device receives light; and
a control unit that operates to control the movable body based on the information on the distance acquired by the ranging device.
